(19) United States
(12) Patent Application Publication
(10) Pub. No.: US 2026/0344007 A1
(43) Pub. Date: Oct. 29, 2026

(54) Method for manufacturing FDSOI device

(71) Applicant: Shanghai Huali Integrated Circuit Corporation, Shanghai (CN)

(72) Inventors: Qiwei WANG, Shanghai (CN); Lei ZHANG, Shanghai (CN); Fanfan CHEN, Shanghai (CN)

(73) Assignee: Shanghai Huali Integrated Circuit Corporation, Shanghai (CN)

(21) Appl. No.: 19/641,573

(22) Filed: Apr. 8, 2026

(30) Foreign Application Priority Data
Apr. 28, 2025 (CN) 2025105546335

(51) Int. Cl. H10D 84/01; H10D 86/00

(52) U.S. Cl. CPC H10D 84/017; H10D 86/201

(57) ABSTRACT

A method for manufacturing an FDSOI device is provided. When a first doped epitaxial layer is formed, sidewalls of a PMOS gate structure include a first spacer and a second spacer. By providing two spacers, the distance between the first doped epitaxial layer and the PMOS gate structure is increased, a protective layer is formed in PMOS gate to cover the first doped epitaxial layer and fill the gap from removing the second spacer, thereby increasing the distance between the PMOS gate structure and the contact hole of the source or drain. This prevents bridging and shorting between the gate and the contact hole of the source or drain, thus ensuring product yield and reliability. Moreover, the second spacer is removed before forming a second doped epitaxial layer on the NMOS gate structure, so as not to increase the distance between the second doped epitaxial layer and the NMOS gate structure.

### FIELD OF TECHNOLOGY

The present disclosure relates to the field of semiconductor technology, and particularly, to a method for manufacturing an FDSOI device.

### BACKGROUND

In existing FDSOI (Fully Depleted Silicon on Insulator) manufacturing processes, the distance between the gate and the contact hole of either the source or the drain in a PMOS region is relatively small compared to that in the NMOS region. It is often necessary to increase the thickness of gate sidewall spacers in order to prevent bridging shorts between the gate and the source or the drain. If the thickness of the gate sidewall spacers is increased to enlarge the distance from the source/drain contact hole to the gate in the PMOS region, then, in order to avoid affecting the similar distance in an NMOS region, it is necessary to reduce the thickness of the gate sidewall spacers in the NMOS region. This complicates the process flow. Moreover, under existing process conditions, reducing the thickness of the gate sidewall spacers in the NMOS region may result in the growth of an SiP layer on a silicon germanium (SiGe) epitaxial layer in the PMOS region, which negatively impacts device performance.

Therefore, to provide a method for manufacturing an FDSOI device that increases the distance between the source/drain contact hole and the gate in the PMOS region, so as to avoid shorting between the source/drain and the gate, thereby improving product yield and reliability, has become an urgent technical problem to be solved.

### SUMMARY

The present disclosure provides a method for manufacturing an FDSOI device.

The method comprises the following steps:
providing a semiconductor structure, wherein the semiconductor structure comprises an NMOS region and a PMOS region, wherein the NMOS region has an NMOS gate structure formed thereon, and the PMOS region has a PMOS gate structure formed thereon;
forming a spacer layer over the semiconductor structure to cover the NMOS gate structure and the PMOS gate structure, wherein the spacer layer comprises a stacked first spacer layer and a second spacer layer on top of the first spacer layer;
removing the first spacer layer and the second spacer layer from a surface of the PMOS region, while retaining the first spacer layer and the second spacer layer on sidewalls of the PMOS gate structure;
forming a first doped epitaxial layer at two sides of the PMOS gate structure on the surface of the PMOS region, wherein the first doped epitaxial layer is laterally spaced apart from both sides of the PMOS gate structure;
removing the second spacer layer from the PMOS region and the NMOS region, and forming a protective layer on a surface of the first doped epitaxial layer in the PMOS region, wherein the protective layer fills a gap between the PMOS gate structure and the first doped epitaxial layer left from removing the second spacer layer;
removing the first spacer layer from a surface of the NMOS region outside the NMOS gate structure while retaining the first spacer layer on sidewalls of the NMOS gate structure; and
forming a second doped epitaxial layer on the surface of the NMOS region at two sides of the NMOS gate structure, wherein the second doped epitaxial layer is laterally spaced apart from both sides, wherein the second doped epitaxial layer is laterally spaced apart from both sides of the NMOS gate structure.

Optionally, the first spacer layer is a silicon oxycarbonitride (SiOCN) layer, and the second spacer layer is a SiCN layer.

Optionally, the protective layer is a silicon carbon nitride (SiOCN) layer.

Optionally, the first doped epitaxial layer is a boron-doped silicon germanium layer.

Optionally, the second doped epitaxial layer is a phosphorus-doped silicon layer.

Optionally, the semiconductor structure comprises a bottom substrate layer, a middle buried insulating layer, and a top semiconductor layer.

Optionally, in the NMOS region, the top semiconductor layer is a silicon layer; in the PMOS region, the top semiconductor layer is a silicon germanium layer.

Optionally, the first doped epitaxial layer is formed by a selective epitaxial growth method, and the second doped epitaxial layer is formed by the selective epitaxial growth method.

Optionally, after forming the first doped epitaxial layer, the second spacer layer is removed using a wet etching method.

Optionally, an isolation structure is formed between the NMOS region and the PMOS region.

As described above, in the method for manufacturing the FDSOI device of the present disclosure, during the formation of the first doped epitaxial layer, the sidewalls of the PMOS gate structure comprise the first spacer layer and the second spacer layer. By providing two spacer layers, the distance between the first doped epitaxial layer and the PMOS gate structure is increased, thereby increasing the distance between the source/drain contact hole and the PMOS gate structure. This prevents shorting between the source/drain contact hole and the gate, thus ensuring product yield and reliability. Furthermore, before forming the second doped epitaxial layer, the second spacer layer is removed, so the distance between the second doped epitaxial layer and the NMOS gate structure is not undesirably increased. In addition, before the second doped epitaxial layer is formed, a protective layer is formed over the first doped epitaxial layer, which prevents the second doped epitaxial layer from growing over the first doped epitaxial layer, thereby further ensuring product yield and reliability.

### BRIEF DESCRIPTION OF THE DRAWINGS

FIG. 1 is a flowchart illustrating a method for manufacturing an FDSOI device according to an embodiment of the present disclosure.

FIG. 2 is a schematic diagram illustrating a semiconductor structure and a formation of an NMOS gate structure and a PMOS gate structure on the semiconductor structure according to an embodiment of the present disclosure.

FIG. 3 is a schematic diagram illustrating a formation of a first spacer layer and a second spacer layer according to an embodiment of the present disclosure.

FIG. 4 is a schematic diagram illustrating a removal of a first spacer layer and a second spacer layer from a surface of the top semiconductor layer outside the gate of the PMOS region according to an embodiment of the present disclosure.

FIG. 5 is a schematic diagram illustrating a formation of a first doped epitaxial layer in the PMOS region according to an embodiment of the present disclosure.

FIG. 6 is a schematic diagram illustrating a removal of a second spacer layer from the PMOS and the NMOS regions according to an embodiment of the present disclosure.

FIG. 7 is a schematic diagram illustrating a formation of a protective layer over the PMOS and the NMOS regions according to an embodiment of the present disclosure.

FIG. 8 is a schematic diagram illustrating a removal of a first spacer layer and the protective layer from a surface of the top semiconductor layer outside the gate in a NMOS region according to an embodiment of the present disclosure.

FIG. 9 is a schematic diagram illustrating a formation of a second doped epitaxial layer in the NMOS region according to an embodiment of the present disclosure.

### REFERENCE NUMERALS

1 Semiconductor structure
100 NMOS region
101 PMOS region
102 Bottom substrate layer
103 Middle buried insulating layer
104 Top semiconductor layer
2 Isolation structure
3 NMOS gate structure
300 Silicon oxide layer
301 Hafnium oxide layer
302 Titanium nitride layer
303 Amorphous silicon layer
304 First hard mask layer
305 Second hard mask layer
4 PMOS gate structure
5 First spacer layer
6 Second spacer layer
7 First photoresist layer
8 First doped epitaxial layer
9 Protective layer
10 Second photoresist layer
11 Second doped epitaxial layer
S1~S7 Steps

### DETAILED DESCRIPTION

The embodiments of the present disclosure will be described below. Those skilled can easily understand advantages and effects of the present disclosure according to contents disclosed by the specification. The present disclosure can also be implemented or applied through other different exemplary embodiments. Various modifications or changes can also be made to all details in the specification based on different points of view and applications without departing from the spirit of the present disclosure.

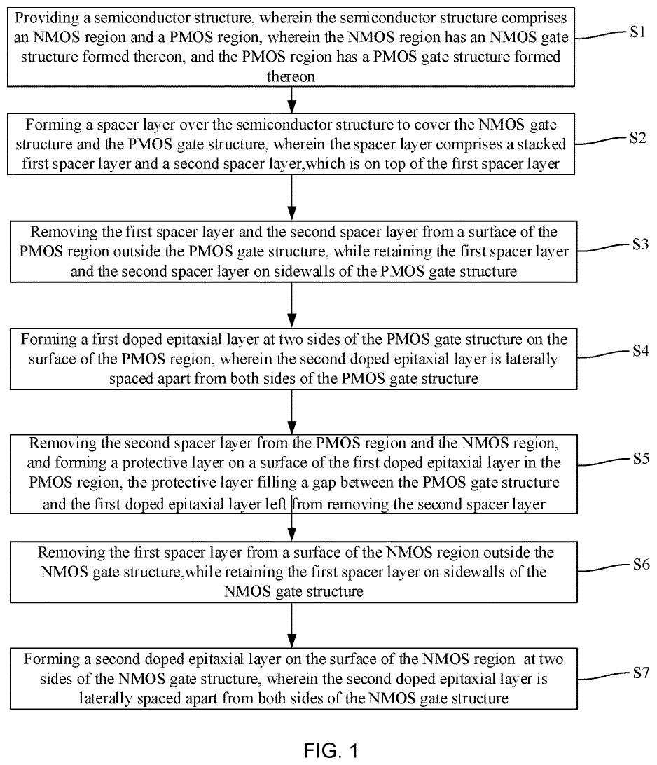

Please refer to FIGS. 1-9. It should be noted that the drawings provided in this disclosure only illustrate the basic concept of the present disclosure in a schematic way, so the drawings only show the components closely related to the present disclosure. The drawings are not necessarily drawn according to the number, shape and size of the components in actual implementation; during the actual implementation, the type, quantity and proportion of each component can be changed as needed, and the components'layout may also be more complicated.

A method for manufacturing an FDSOI device is provided in this embodiment, as shown in FIG. 1, the method comprises:

S1: providing a semiconductor structure, wherein the semiconductor structure comprises an NMOS region and a PMOS region, wherein the NMOS region has an NMOS gate structure formed thereon, and the PMOS region has a PMOS gate structure formed thereon;

S2: forming a spacer layer over the semiconductor structure to cover the NMOS gate structure and the PMOS gate structure, wherein the spacer layer comprises a stacked first spacer layer and a second spacer layer which is on top of the first spacer layer;

S3: removing the first spacer layer and the second spacer layer from a surface of the PMOS region outside the PMOS gate structure, while retaining the first spacer layer and the second spacer layer on sidewalls of the PMOS gate structure;

S4: forming a first doped epitaxial layer at two sides of the PMOS gate structure on the surface of the PMOS region, wherein the second doped epitaxial layer is laterally spaced apart from both sides of the PMOS gate structure;

S5: removing the second spacer layer from the PMOS region and the NMOS region, and forming a protective layer on a surface of the first doped epitaxial layer in the PMOS region, the protective layer filling a gap between the PMOS gate structure and the first doped epitaxial layer left from removing the second spacer layer;

S6: removing the first spacer layer from a surface of the NMOS region outside the NMOS gate structure, while retaining the first spacer layer on sidewalls of the NMOS gate structure; and

S7: forming a second doped epitaxial layer on the surface of the NMOS region at two sides of the NMOS gate structure, wherein the second doped epitaxial layer is laterally spaced apart from both sides of the NMOS gate structure.

The following is a detailed description of the method for manufacturing the FDSOI device according to this embodiment, with reference to the accompanying drawings.

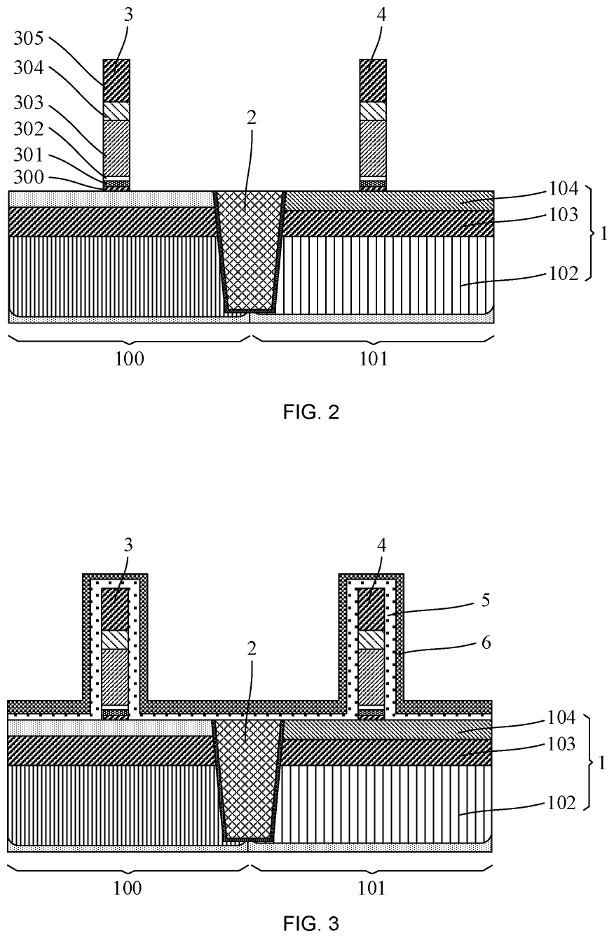

First, please refer to FIG. 2, and Step S1 is performed:

A semiconductor structure 1 is provided, which comprises an NMOS region 100 and a PMOS region 101. An NMOS gate structure 3 is formed in the NMOS region 100, and a PMOS gate structure 4 is formed in the PMOS region 101.

As an example, the semiconductor structure 1 is an SOI structure, which comprises, from bottom to top, a substrate layer 102, a buried insulating layer 103, and a top semiconductor layer 104; for the NMOS region, where the carriers are electrons, the top semiconductor layer 104 is a silicon layer, which facilitates electron mobility; for the PMOS region, where the carriers are holes, the top semiconductor layer 104 is a silicon-germanium layer, which facilitates hole mobility.

As an example, an isolation structure 2 is disposed between the NMOS region 100 and the PMOS region 101 to isolate them. In this embodiment, the isolation structure 2 is a shallow trench isolation (STI) structure.

As an example, the top semiconductor layer 104 covered by the NMOS gate structure 3 serves as an NMOS channel region, with the source region and drain region of the NMOS respectively located on both sides of the NMOS channel region; the top semiconductor layer 104 covered by the PMOS gate structure 4 serves as a PMOS channel region, with the source region and drain region of the PMOS respectively located on both sides of the PMOS channel region.

As an example, the NMOS gate structure 3 comprises, in a bottom-to-top stack, a silicon oxide layer 300, a hafnium oxide layer 301, a titanium nitride layer 302, an amorphous silicon layer 303, a first hard mask layer 304, and a second hard mask layer 305. The silicon oxide layer 300 acts as an interface layer to reduce interface state density. The hafnium oxide layer 301 acts as a high-K dielectric layer, the titanium nitride layer 302 serves as a work function metal layer, and the amorphous silicon layer 303 functions as a dummy gate layer. The first hard mask layer 304 and the second hard mask layer 305 are used as etching masks for the gate structure. The first hard mask layer 304 is a silicon nitride layer, and the second hard mask layer 305 is a silicon oxide layer. Similarly, the PMOS gate structure 4 also comprises, from bottom to top, a silicon oxide layer, a hafnium oxide layer, a titanium nitride layer, an amorphous silicon layer, a first hard mask layer, and a second hard mask layer.

Next, please refer to FIG. 3, and Step S2 is performed:

A spacer layer is formed over the semiconductor structure 1, covering both the NMOS gate structure 3 and the PMOS gate structure 4. The spacer layer comprises a stacked structure of a first spacer layer 5 and a second spacer layer 6 over the first spacer layer.

As an example, the first spacer layer 5 and the second spacer layer 6 are stacked bottom-up. In this embodiment, the first spacer layer 5 is an SiOCN layer, and the second spacer layer 6 is an SiCN layer. In other embodiments, other suitable materials may be used and are not limited to this embodiment.

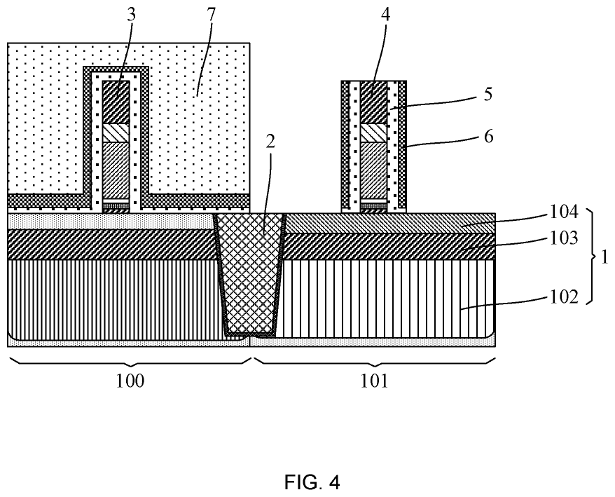

Next, please refer to FIG. 4, and Step S3 is performed:

The first spacer layer 5 and the second spacer layer 6 over the surface of the PMOS region 101 are removed from the top semiconductor layer 104, while the first spacer layer 5 and the second spacer layer 6 located on the sidewalls of the PMOS gate structure 4 are retained, wherein the end of the second spacer layer 6 on the sidewalls sits on the footing of the first spacer layer 5.

As an example, a first photoresist layer 7 is formed over both the NMOS region 100 and the PMOS region 101. The first photoresist layer 7 is then patterned to expose the PMOS region 101. Thereafter, a dry etching process or similar is used to remove the first spacer layer 5 and the second spacer layer 6 from the top surface of gate and the uncovered surface of the top semiconductor layer 104 outside of the gate in the PMOS region 101 while retaining the first spacer layer 5 and the second spacer layer 6 on the upper potions of the sidewalls of the PMOS gate of the PMOS gate structure 4.

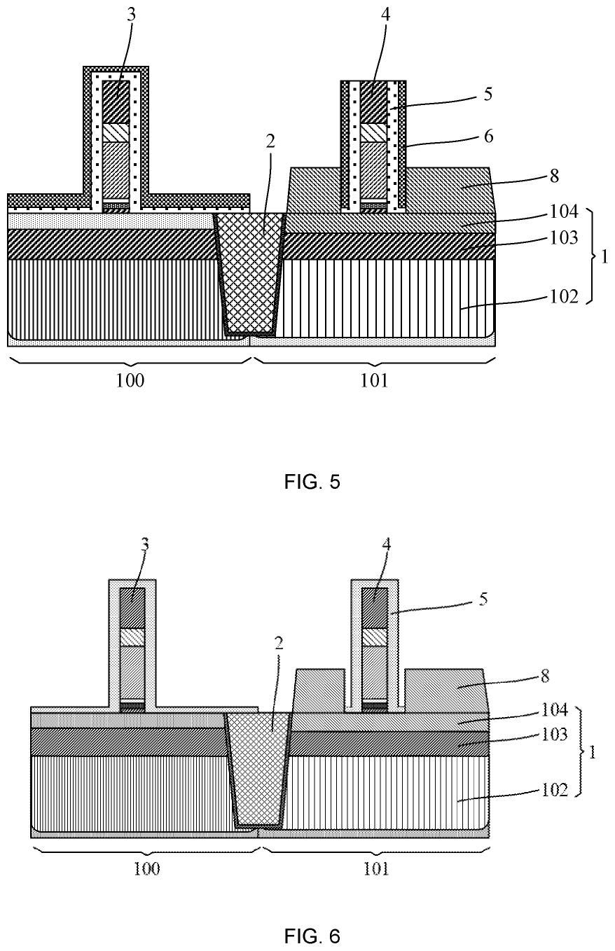

Next, please refer to FIG. 5, and Step S4 is performed:

A first doped epitaxial layer 8 is formed on the surface of the PMOS region 101 and NMOS region 100, followed by removing the photo resist layer 7 along with the first doped epitaxial layer 8 from the NMOS region, and partially removing the first doped epitaxial layer 8 from the top and the upper sidewalls of the gate in the PMOS region, resulting in the first doped epitaxial layer 8 disposed on both sides of the PMOS gate structure 4 in a separated manner.

As an example, the first doped epitaxial layer 8 is a boron-doped silicon-germanium layer, which is formed by a selective epitaxial growth process. During the process, silane (SiH₄) and germane (GeH₄) are used as reactant gases, while diborane (B₂H₆) is introduced as the dopant. Boron atoms are incorporated into the growing silicon-germanium layer during the epitaxy process.

As an example, during formation of the first doped epitaxial layer 8, the sidewalls of the PMOS gate structure 4 comprise both the first spacer layer 5 and the second spacer layer 6. That is, the gap distance between the first doped epitaxial layer 8 and the PMOS gate structure 4 equals to the combined thickness of these two spacer layers, thereby increasing the spacing between the first doped epitaxial layer 8 and the PMOS gate structure 4.

As an example, the first doped epitaxial layer 8 may function as a raised source and drain region for the PMOS device. Because of the increased spacing introduced by the dual-layer sidewalls, the distance between the PMOS gate structure 4 and the contact hole for the source or the drain is enlarged. This helps to avoid bridging or short circuits between the contact hole and the gate, thereby improving product yield and device reliability.

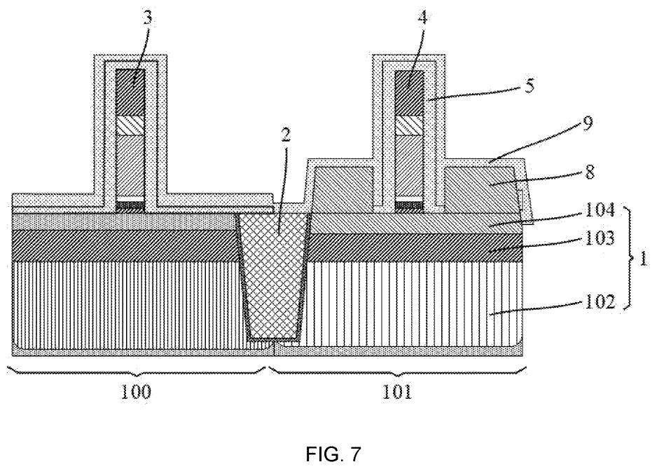

Next, please refer to FIGS. 6 and 7, and Step S5 is performed:

The second spacer layer 6 is removed from both PMOS and NMOS regions, and a protective layer 9 is formed on the surface of the first doped epitaxial layer 8 and the first spacer layer 5 on the PMOS gate structure 4 in the PMOS region 101.

As an example, after the first doped epitaxial layer 8 is formed, a wet etching process is used to remove the second spacer layer 6, and the protective layer 9 is then formed on the exposed surface of the first doped epitaxial layer 8, including the gap left by the removed second spacer layer 6 between the sidewall of the PMOS gate structure and the first doped epitaxial layer 8.

As an example, the protective layer 9 is a dielectric layer. In this embodiment, the protective layer 9 is an SiOCN layer with a thickness of about 60 Å.

As an example, the protective layer 9 may also cover the NMOS gate structure 3, the surface of the top semiconductor layer 104 in the NMOS region 100, and the PMOS gate structure 4. In another embodiment, the protective layer 9 may be formed only over the surface of the first doped epitaxial layer 8 in the PMOS region 101, depending on design requirements.

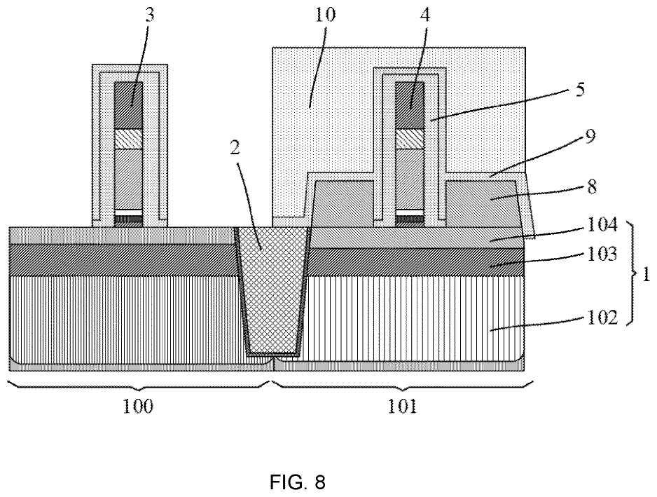

Next, please refer to FIG. 8, and Step S6 is performed:

The first spacer layer 5 over the surface of the NMOS region 100 outside the NMOS gate structure 3 is removed, the remaining portion of the first spacer layer 5 stays on the sidewalls of the NMOS gate structure 3.

As an example of the process, during the removal of the first spacer layer 5 from the top semiconductor layer 104 in the NMOS region 100, the protective layer 9 located on top of the first spacer layer 5 is also removed. Specifically, a second photoresist layer 10 is formed over both the NMOS and PMOS regions. The second photoresist layer 10 is then patterned to expose the NMOS region 100, and a dry etching process is followed to remove the first spacer layer 5 and the protective layer 9 from the surface of top semiconductor layer 104 in the NMOS region while retaining the first spacer layer 5 and the protective layer 9 on the sidewalls of the NMOS gate structure 3, wherein ends of the protective layer 9 rest on the footings of the first spacer layer.

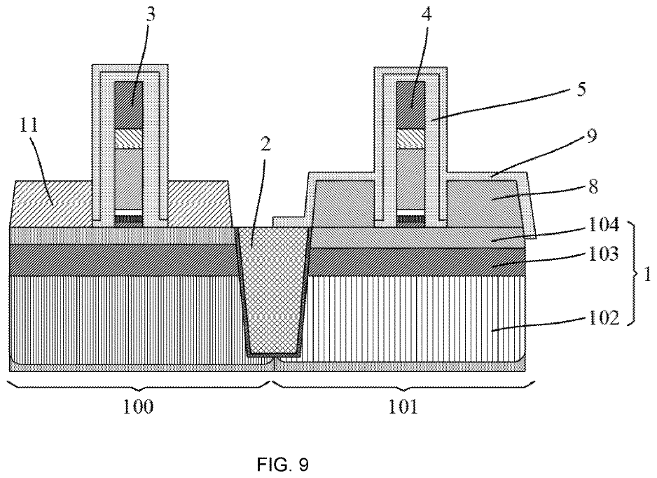

Next, please refer to FIG. 9, and Step S7 is performed:

A second doped epitaxial layer 11 is formed on the surface of the NMOS region 100, with the layer disposed on both sides of the NMOS gate structure 3 in a separated manner The photoresist layer 10 over the PMOS region is removed at the end.

As an example, the second doped epitaxial layer 11 is a phosphorus-doped silicon layer, which is formed using a selective epitaxial growth process. Silane (SiH₄) is used as the reactant gas, and phosphine (PH₃) or a similar phosphorus-containing gas is introduced as the dopant. Phosphorus atoms are incorporated into the growing silicon layer during the deposition process.

As an example, before forming the second doped epitaxial layer 11, the surface of the first doped epitaxial layer 8 is covered with a second photoresist 10 over the protective layer 9, the second photoresist 10 prevents growth of the second doped epitaxial layer 11 on the PMOS region, thereby enhancing yield and reliability.

As an example, the second spacer layer 6 is removed before the formation of the second doped epitaxial layer 11, so the spacing between the second doped epitaxial layer 11 and the NMOS gate structure 3 is not unnecessarily increased.

In summary, in the method for manufacturing the FDSOI device provided by the present disclosure, when a first doped epitaxial layer is formed, sidewalls of a PMOS gate structure comprise a first spacer layer and a second spacer layer. By employing the two spacer layers, the distance between the first doped epitaxial layer and the PMOS gate structure is increased. This, in turn, increases the distance between contact holes of the source and drain and the PMOS gate structure, thereby preventing bridging and shorting between the contact holes and the gate, and ensuring product yield and reliability. Furthermore, before forming a second doped epitaxial layer, the second spacer layer is removed so that no additional distance is introduced between the second doped epitaxial layer and the NMOS gate structure; in addition, before forming the second doped epitaxial layer, a protective layer is formed to cover the first doped epitaxial layer, which prevents the second doped epitaxial layer from being formed on the first doped epitaxial layer, further ensuring product yield and reliability. Therefore, the present disclosure effectively overcomes various shortcomings in the existing technology and has high industrial utilization value.

The above-mentioned embodiments are merely illustrative of the principle and effects of the present disclosure instead of restricting the scope of the present disclosure. Any person skilled in the art may modify or change the above embodiments without violating the principle of the present disclosure. Therefore, all equivalent modifications or changes made by those who have common knowledge in the art without departing from the spirit and technical concept disclosed by the present disclosure shall be still covered by the claims of the present disclosure.

What is claimed is:

1. A method for manufacturing an FDSOI device, comprising:
providing a semiconductor structure, wherein the semiconductor structure comprises an NMOS region and a PMOS region, wherein the NMOS region has an NMOS gate structure formed thereon, and the PMOS region has a PMOS gate structure formed thereon;
forming a spacer layer over the semiconductor structure to cover the NMOS gate structure and the PMOS gate structure, wherein the spacer layer comprises a stacked first spacer layer and a second spacer layer which is on top of the first spacer layer;
removing the first spacer layer and the second spacer layer from a surface of the PMOS region outside the PMOS gate structure, while retaining the first spacer layer and the second spacer layer on sidewalls of the PMOS gate structure;
forming a first doped epitaxial layer at two sides of the PMOS gate structure on t he surface of the PMOS region, wherein the first doped epitaxial layer is laterally spaced apart from both sides of the PMOS gate structure;
removing the second spacer layer from the PMOS region and the NMOS region, and forming a protective layer on a surface of the first doped epitaxial layer in the PMOS region, wherein the protective layer fills a gap between the PMOS gate structure and the first doped epitaxial layer left from removing the second spacer layer;
removing the first spacer layer from a surface of the NMOS region outside the N MOS gate structure, while retaining the first spacer layer on sidewalls of the NMOS g ate structure; and
forming a second doped epitaxial layer at two sides of the NMOS gate structure on the surface of the NMOS region, wherein the second doped epitaxial layer is laterally spaced apart from both sides of the NMOS gate structure.

2. The method for manufacturing the FDSOI device according to claim 1, wherein the first spacer layer is a SiOCN layer, and the second spacer layer is a SiCN layer.

3. The method for manufacturing the FDSOI device according to claim 1, wherein the protective layer is a silicon oxycarbonitride (SiOCN) layer.

4. The method for manufacturing the FDSOI device according to claim 1, wherein the first doped epitaxial layer is a boron-doped silicon germanium layer.

5. The method for manufacturing the FDSOI device according to claim 1, wherein the second doped epitaxial layer is a phosphorus-doped silicon layer.

6. The method for manufacturing the FDSOI device according to claim 1, wherein the semiconductor structure comprises a bottom substrate layer, a middle buried insulating layer, and a top semiconductor layer.

7. The method for manufacturing the FDSOI device according to claim 6, wherein the top semiconductor layer is a silicon layer in the NMOS region, and the top semiconductor layer is a silicon germanium layer in the PMOS region.

8. The method for manufacturing the FDSOI device according to claim 1, wherein the first doped epitaxial layer is formed by a selective epitaxial growth method, and the second doped epitaxial layer is also formed by a selective epitaxial growth method.

9. The method for manufacturing the FDSOI device according to claim 1, wherein after forming the first doped epitaxial layer, the second spacer layer is removed by a wet etching method.

10. The method for manufacturing the FDSOI device according to claim 1, wherein an isolation structure is formed between the NMOS region and the PMOS region.
